(19) United States
(12) Patent Application Publication
(10) Pub. No.: US 2015/0069380 A1
(43) Pub. Date: Mar. 12, 2015

(54) VARISTOR-TRANSISTOR HYBRID DEVICES

(71) Applicants: Raghvendra K. Pandey, Austin, TX (US); William Albert Stapleton, San Marcos, TX (US); Ivan Sutanto, Austin, TX (US); Amanda Scantlin, Buda, TX (US)

(72) Inventors: Raghvendra K. Pandey, Austin, TX (US); William Albert Stapleton, San Marcos, TX (US); Ivan Sutanto, Austin, TX (US); Amanda Scantlin, Buda, TX (US)

(21) Appl. No.: 14/365,025

(22) PCT Filed: Sep. 14, 2012
(86) PCT No.: PCT/US2012/055503

§ 371 Date: Nov. 26, 2014

Related U.S. Application Data
(60) Provisional application No. 61/569,379, filed on Dec. 12, 2011.

(51) Int. Cl. H01L 29/24; H01L 29/8605; H01L 29/45; H01L 29/51; H01L 29/78; H01L 29/82

(52) U.S. Cl. CPC H01L 29/24; H01L 29/78; H01L 29/82; H01L 29/45; H01L 29/517; H01L 29/8605
USPC 257/43

(57) ABSTRACT

Simple transistor structures may be made using iron-titanate substrates. These structures may operate as varistor-transistor hybrid devices. The iron-titanate substrates may include pseudobrookite (PsB) substrates or 55 atomic % ilmenite (FeTiO3) and 45 atomic % hematite (Fe₂O₃) substrates (e.g., IHC45 substrates). The transistor structure may produce modified I-V characteristics when a gate voltage (applied through a gate oxide), a biasing voltage, or a magnetic field is applied to the structure.

### STATEMENT ON U.S. FEDERALLY SPONSORED RESEARCH OR DEVELOPMENT

This invention was made with government support under NSF Grant No. 1025395 awarded by the National Science Foundation. Accordingly, the United States Government may have certain rights in this invention.

### BACKGROUND

1. Field of the Invention

The present invention relates to devices for use in electronics. More particularly, the invention relates to hybrid devices and the methods of making and characterizing properties of the devices. Examples of devices formed are hybrid devices such as bipolar signal amplifiers, tunable devices for low frequencies, non-conservative low pass filters, and tunable transistors. These devices may use substrates made from the iron titanate family exemplified by IHC45 and PsB.

2. Description of Related Art

Pseudobrookite (Fe₂TiO₅, which is referred to as PsB herein) is naturally found as a mineral. PsB has been studied extensively for photo-catalysis reactions in search of alternative forms of energy. PsB is environmentally stable and environmentally friendly. PsB is also a wide band gap semiconductor with a band gap of approximately 2.3 eV. PsB has n-type semiconducting nature and has an electron mobility (6.3 cm²V⁻¹s⁻¹), which is relatively high compared to the values for many oxides as evidenced in R. K. Pandey, L. F. Deravi, N. N. Patil, P. Kale, J. Zhong, J. Dou, L. Navarrete, R. Schad and M Shamzuzhoa, “Magnetic Semiconductors in Fe—Ti-Oxide Series and their Potential Applications”, IEEE Proceedings of the 8th International Conference on Solid State and Integrated Circuit Technology, ICSICT (2006), Part 2, (2006), 992. PsB is also found to exhibit extreme resistance to high levels of radiation. The combination of these properties led to studies of PsB for applications.

Relatively large crystals of pseudobrookite have previously been grown using high temperature solution growth methods described in “Magnetic Semiconductors in Fe—Ti-Oxide Series and their Potential Applications”. FIG. 1 is a TEM (transmission electron microscopy) image of a PsB crystal grown using the high temperature solution method. The high atomic periodicity shown in FIG. 1 confirms the device quality of single crystal PsB. PsB's crystal structure is orthorhombic with the lattice constants of: a=0.979 nm, b=0.993 nm, and c=0.372 nm. The point group is mmm and, therefore, the unit cell has center of symmetry. The n-type semiconductor nature of PsB was confirmed by the negative sign of the Seebeck coefficient, which is −35 μV/K at room temperature. The room temperature dielectric constant of PsB was found to be about 1200 at 1 kHz, which is a relatively high value (as shown by R. K. Pandey, P. Padmini, P. Kale, J. Dou, C. Lohn, R. Schad, R. Wilkins, and W. Geerts, “Multifunctional Nature of Modified Iron Titanates and their Potential Applications”, Ceramic Transactions, vol. 226, (2011), 61). Many physical properties of PsB as well as its radhard properties have been discussed in “Magnetic Semiconductors in Fe—Ti-Oxide Series and their Potential Applications” and in R. K. Pandey, P. Padmini, R. Schad, J. Dou, H. Stern, R. Wilkins, R. Dwivedi, W. J. Geerts and C. O'Brien, “Novel Magnetic-Semiconductors in Modified FeTiO₃ for Radhard Electronics”, J. Electro-Ceramic, DOI 10.1007/s10832-007-9390-1, (2008); (2009) 22:334-341.

A room temperature, wide band gap semiconductor may be derived from two minerals found in abundance—ilmenite, FeTiO₃ and hematite, Fe₂O₃. Ilmenite and hematite are used as chemicals for ceramic processing and are widely available from chemical supply houses in high purity grades at reasonable costs. Materials made from ilmenite and hematite can generally be written as (1−x)FeTiO₃.xFe₂O₃ and are commonly known as ilmenite-hematite or simply as IH. A certain material derived from ilmenite and hematite with x=0.45 from this formulation has the chemical formula 0.55 FeTiO₃.0.45 Fe₂O₃. Such a material is referred to herein as IHC45, where C stands for ceramic. Other forms of IH can be film (IHF) or single crystal (IHX).

IH is an interesting class of oxide with a unique combination of high dielectric constant, wide band gap semiconductor with a value between 2.4-2.8 eV, and ferromagnetism with the magnetic Curie point well above room temperature. Because IH is an oxide, its ceramics are environmentally stable and robust. The combination of strong mechanical properties coupled with unique physical properties make the IH class of materials highly suited for many applications including for some emerging technologies such as magneto-electronics, hybrid devices, space electronics, high temperature electronics as well as for advancement of oxide based microelectronics. Because of its radhard nature, IH is an attractive material for the development of space electronics in particular. Many of its fundamental properties as well as device properties have been reported in multiple publications. For example, properties have been reported in Feng Zhou, Sushma Kotru and Raghvendra K. Pandey, “Nonlinear current-voltage characteristics of ilmenite-hematite ceramic” Materials Letter, 57, (2003), 2104 and L. Navarette, J. Dou, D. M. Allen, R. Schad, P. Padmini, P. Kale and R. K. Pandey, “Magnetization and Curie Temperature of Ilmenite-Hematite Solid solution Ceramics”, J. Am. Ceram. Soc., 89(5), (2006), 1601.

### SUMMARY

In certain embodiments, a semiconductor device includes an iron-titanate substrate with a gate oxide structure formed on the substrate. The gate oxide structure may include a first metal contact on the substrate, a gate oxide formed on the first metal contact, and a second metal contact formed on the gate oxide. A metal source and a metal drain may be formed on the substrate on opposing sides of the gate oxide structure. In some embodiments, the device operates as a field effect transistor when a gate voltage is applied to the device. In some embodiments, the iron-titanate substrate is a 55% (atomic) ilmenite and 45% (atomic) hematite substrate. In some embodiments, the gate oxide is CaCu₃Ti₄O₁₂ (CCTO).

In certain embodiments, a semiconductor device includes an iron-titanate substrate with a metal bias voltage contact formed on the substrate. A metal source and a metal drain may be formed on the substrate on opposing sides of the gate oxide structure. In some embodiments, the device operates as a transistor when a biasing voltage is applied to the device. In some embodiments, the iron-titanate substrate is a pseudobrookite (PsB) substrate. In some embodiments, the iron-titanate substrate is a 55% (atomic) ilmenite and 45% (atomic) hematite substrate.

In certain embodiments, a semiconductor varistor device includes an iron-titanate substrate with a metal source and a metal drain formed on the substrate. A magnetic field generating device may generate a magnetic field in a direction perpendicular to a flow of current between the source and the drain. In certain embodiments, the generated magnetic field is used to tune the varistor device during use. In some embodiments, the semiconductor varistor device is a magnetically tuned voltage amplifying transistor. In some embodiments, the semiconductor varistor device is a magnetically tuned current amplifying transistor.

In certain embodiments, a bipolar signal amplifier device includes pseudobrookite (PsB). The device amplifies an output signal from the device when a DC bias voltage is applied to the device. The gain from the device may be bipolar (either positive or negative gain). In some embodiments, the bias voltage is a DC bias voltage of either ±2 V or ±4 V. In some embodiments, the device includes single crystal PsB. In some embodiments, the device includes a ceramic substrate of PsB.

In certain embodiments, a tunable signal amplifier device includes pseudobrookite (PsB). An output signal of the device may be tunable by varying an AC drain voltage applied to the device while maintaining a constant bias voltage. The device may amplify the output signal over a frequency range of about 20 Hz to about 22 kHz.

In certain embodiments, a tunable filter device includes pseudobrookite (PsB). An output signal of the device may be tunable by varying an AC drain voltage applied to the device while maintaining a constant bias voltage. The device may pass output signals in a frequency range of about 20 Hz to about 22 kHz. A cutoff point of the device may be about 38 kHz.

In certain embodiments, a low pass filter device includes ilmenite and hematite. The device passes output signals in a frequency range of about 20 Hz to about 420 kHz. In some embodiments, an output signal of the device is tunable by varying an AC drain voltage applied to the device while maintaining a constant bias voltage. In some embodiments, an output signal of the device is tunable by varying a DC bias voltage applied to the device while maintaining a constant drain voltage. In certain embodiments, the device includes 55% (atomic) ilmenite and 45% (atomic) hematite.

In certain embodiments, a switching device includes ilmenite and hematite. The device provides a final output current in less than about 10 μs regardless of an input voltage to the device. In certain embodiments, the device includes 55% (atomic) ilmenite and 45% (atomic) hematite.

In certain embodiments, a magnetic field is applied to modify the signal output. In some embodiments, the output signals are modified by applying a gate voltage or a bias voltage. Sources and drains may be formed on the substrate by forming metal contacts. Gates and bias voltages may be formed as described herein.

### BRIEF DESCRIPTION OF THE DRAWINGS

Features and advantages of the methods and apparatus of the present invention will be more fully appreciated by reference to the following detailed description of presently preferred but nonetheless illustrative embodiments in accordance with the present invention when taken in conjunction with the accompanying drawings in which:

FIG. 1 depicts a TEM (transmission electron microscopy) image of PsB single crystal.

FIG. 2 depicts an I-V curve for single crystal PsB with zero bias voltage.

FIG. 3 depicts a circuit diagram used to determine the response of I-V as a function of the bias voltage (V_{b}) for single crystal PsB (a 3-point I-V measurement).

FIG. 4 depicts the I_{d}-V_{d} curve for positive V_{b}.

FIG. 5 depicts the I_{d}-V_{d} curve for negative V_{b}.

FIG. 6 depicts a plot of gain factor at ±two bias voltages.

FIG. 7 depicts a composite plot of gain factor at several bias voltages.

FIG. 8 depicts a plot of gain factor for IHC45 at several bias voltages.

FIG. 9 depicts a plot of gain factor for a ceramic substrate of PsB at several bias voltages.

FIG. 10 depicts a circuit diagram used to determine the response of I-V in AC (alternating current) mode as a function of an AC bias voltage (V_{b}) for single crystal PsB (a 3-point I-V measurement).

FIG. 11 depicts the frequency dependence of the drain current (I_{d}) as a function of drain voltage (V_{d}) at constant bias voltage (V_{b}=3 VDC).

FIG. 12 depicts the frequency dependence of the drain current (I_{d}) as a function of bias voltage (V_{b}) at constant drain voltage (V_{d}=3 Vₚₚ).

FIG. 13 depicts the frequency dependence of drain current in dB unit as a function of drain voltage at constant bias voltage (V_{b}=3 VDC).

FIG. 14 depicts the I-V curve found for the IHC45 ceramic sample.

FIG. 15 shows the I-V of a typical IHC45 ceramic sample diode in AC mode at 60 Hz frequency.

FIG. 16 depicts the I-V characteristics of IHC45 ceramic sample with AC input at varying frequencies and varying drain voltage (V_{d}) and fixed bias voltage (V_{b}).

FIG. 17 depicts the I-V characteristics of IHC45 ceramic sample with AC input at varying frequencies and varying bias voltage (V_{b}) and fixed drain voltage (V_{d}).

FIG. 18 depicts the output signal, I_{d}, as a function of time (inverse of the frequency) for IHC45 ceramic.

FIG. 19 depicts a schematic representation of an embodiment of a gate oxide structure.

FIG. 20 depicts I-V curves for the structure shown in FIG. 19 as a function of applied gate voltage, V_{g}.

FIG. 21 depicts the transistor drain current plotted as a function of the drain voltage.

FIG. 22 depicts I-V curves for the structure shown in FIG. 19 for positive drain voltage, V_{d}, as a function of gate voltage.

FIG. 23 depicts I-V curves for the structure shown in FIG. 19 for negative drain voltage, V_{d}, as a function of gate voltage.

FIG. 24 depicts a schematic representation of an embodiment of a bias voltage structure.

FIG. 25 depicts I-V curves for the structure shown in FIG. 24 with the bias voltage, V_{b}, ranging between ±1-3 V and the drain voltage, V_{d}, ranging between ±8 V.

FIG. 26 depicts I-V curves for the structure shown in FIG. 24 as a function of the positive bias voltage.

FIG. 27 depicts I-V curves for the structure shown in FIG. 24 as a function of the negative bias voltage.

FIG. 28 depicts I-V curves for the structure shown in FIG. 24 as a function of small values of the bias voltage (e.g., V_{b}≦1 V).

FIG. 29 depicts the frequency dependence of output current for the structure shown in FIG. 24 in varistor mode while keeping the drain voltage constant at 2 Vₚₚ.

FIG. 30 depicts the frequency dependence of output current for the structure shown in FIG. 24 in transistor mode while keeping the drain voltage constant at 2 Vₚₚ.

FIG. 31 depicts the difference between the varistor mode and the transistor mode for the structure shown in FIG. 24 at a constant bias voltage of 3 V.

FIG. 32 depicts the difference between the varistor mode and the transistor mode for structure shown in FIG. 24 with the PsB substrate at a constant bias voltage of 4 V.

FIG. 33 depicts a composite of several I-V curves for the PsB substrate as a function of varying bias voltage, V_{b}.

FIG. 34 depicts transistor drain current versus drain voltage as a function of gate voltage for the structure shown in FIG. 19 with a PsB substrate (e.g., substrate 102 is PsB) and SiO₂ as the gate oxide (e.g., gate oxide 110 is SiO₂).

FIG. 35 depicts a schematic for current-voltage determination with magnetic field.

FIG. 36 depicts V-I characteristics of an IHC 45 varistor with varying magnetic fields.

FIG. 37 depicts V_{d}-I_{d} characteristics of an IHC45 transistor with varying magnetic fields.

FIG. 38 depicts the ΔI_{d}-V_{d} of an IHC 45 transistor in reverse mode with varying H at room temperature.

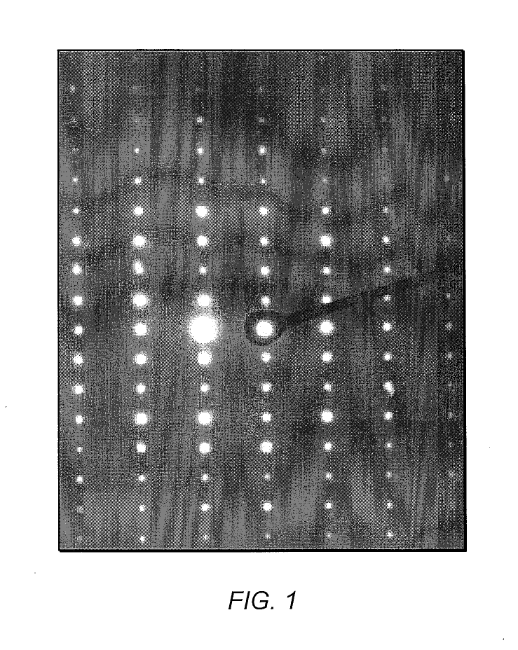

While the invention is susceptible to various modifications and alternative forms, specific embodiments thereof are shown by way of example in the drawings and will herein be described in detail. The drawings may not be to scale. It should be understood that the drawings and detailed description thereto are not intended to limit the invention to the particular form disclosed, but to the contrary, the intention is to cover all modifications, equivalents and alternatives falling within the spirit and scope of the present invention as defined by the appended claims.

### DETAILED DESCRIPTION OF EMBODIMENTS

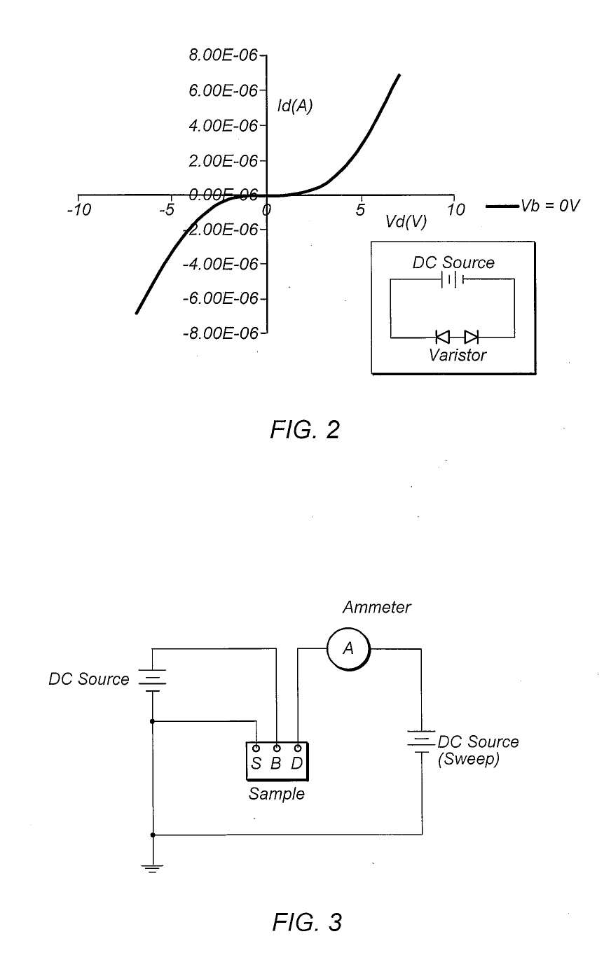

The current-voltage (I-V) characteristics of a PsB crystal were determined using a two point current-voltage measurement in DC (direct current) mode. FIG. 2 depicts the I-V curve found for PsB single crystal with bias voltage (V_{b})=0 V. The two point current-voltage measurement produced a highly nonlinear characteristic usually found for varistor devices. A varistor device is modeled as two Schottky diodes in parallel configuration (as shown in the insert in FIG. 2). The varistor device is also called a VDR (voltage dependent resistor) because at low voltage it has high impedance and at high voltage it has low impedance. This feature of the varistor makes the varistor (or VDR) uniquely suitable for circuit protection.

The varistor curve obtained for PsB single crystal, shown in FIG. 2, shows a well defined shoulder in both forward and reverse directions. In the forward mode, the crystal switches at about 1.67 V while in the reverse mode, the switching voltage (Vₛ) is about 0.83 V, or about ½ the value of the forward mode. This asymmetry is also found for many varistors as well as for well established SiC (silicon carbide) varistors, which are widely used for power electronics and for high temperature electronics. The PsB single crystal, however, switches at relatively low voltages and, thus, is particularly interesting for protection of conventional integrated circuits and microelectronics circuitry. Additionally, the radhard nature of PsB based nonlinear I-V characteristics has been documented in “Multifunctional Nature of Modified Iron Titanates and their Potential Applications” and “Novel Magnetic-Semiconductors in Modified FeTiO₃ for Radhard Electronics”.

In general a varistor is represented by the formula:

I=aV^{α}. (1)

where, α is defined as the non-linear coefficient of a varistor and is given by:

α=(log I₂−log Iᵢ)/(log V₂−log Vᵢ). (2)

The parameter a is 2.54 for PsB single crystal and is the highest value for all the iron titanate based varistors.

FIG. 3 depicts a circuit diagram used to determine the response of I-V in DC mode as a function of a DC bias voltage (V_{b}) for single crystal PsB (a 3-point I-V measurement). In FIG. 3, S stands for the source, which is grounded; D for drain and B for bias. The drain voltage (V_{d}) is swept for ±10 V and V_{b} is altered manually for V_{b}=+1 V to +5 V and V_{b}=−1 V to −5 V. For each value of V_{b}, a large number of data points were collected and analyzed.

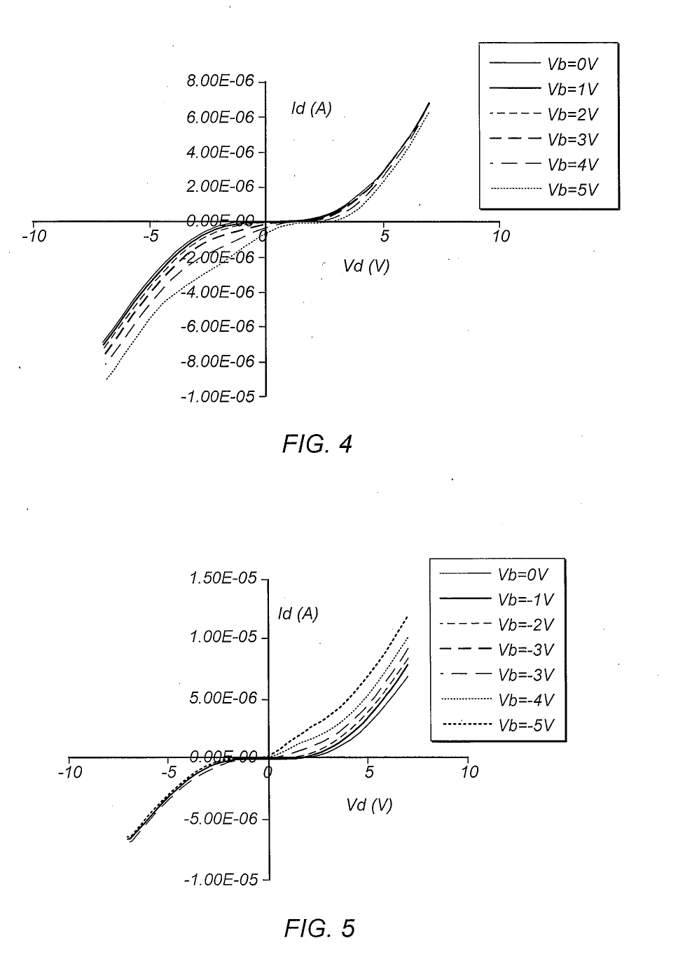

FIG. 4 depicts the I_{d}-V_{d} curve for positive V_{b}. FIG. 5 depicts the I_{d}-V_{d} curve for negative V_{b}. The introduction of a bias voltage dramatically alters the nature of the I_{d}-V_{d} curve, as shown in FIGS. 4 and 5. As shown in FIG. 4, with positive V_{b}, the I_{d}-V_{d} curves appear to cluster together for positive values of V_{d} but open up in the negative direction of V_{d}. With negative V_{b}, as shown in FIG. 5, the picture is opposite. Also, the I_{d}-V_{d} curve suffers noticeable distortion for V_{b}=+4 V and +5 V as well as for V_{b}=−4 V and −5 V.

The current gain (gain factor)(G) may be defined as:

G=(I_{d,x}−I_{d,O})/(I_{b,x})=ΔI_{d,x}/I_{b,x}; (3)

where: I_{d,x} is the drain current corresponding to bias voltage V_{b,x} at a constant V_{d}; I_{d,0} is the drain current at V_{b}=0 and at the same V_{d} as for I_{d,x}; and I_{b,x} is the bias current corresponding to I_{d,x}. G can have both negative and positive values depending upon the current directions.

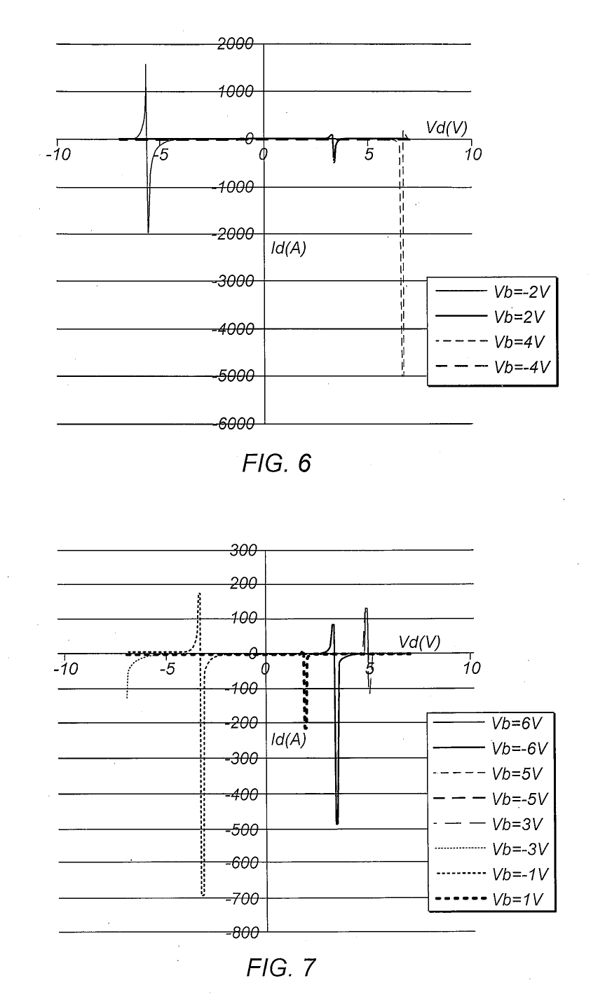

FIG. 6 plots G vs. V_{d} for V_{b}=+2 V and −2 V, and V_{b}=+4 V and −4 V as two examples. G is shown to be bipolar and undergoes a strong and sharp resonance at V_{b}=−2 V and V_{b}=+4 V. The signal outputs for the opposite values of these V_{b} also show resonance but the magnitudes are very small and therefore hardly noticeable. The bipolarity of G corresponding to V_{b}=−2 V is quite noticeable with G varying from approximately +1500 in the positive direction and −2000 in the negative direction. The resonance takes place in a narrow range of V_{d} and may be important for applications such as sensors and detectors. The largest value of G is obtained for V_{b}=+4 V, which is approximately −5000. Such a large gain factor may be advantageous for use in multiple microelectronics devices and circuits for amplification of signal.

Such resonances take place for each value of V_{b}, as shown in FIG. 7. As may be expected, the values corresponding to V_{b}=−2 V and +4 V are much larger than the impact of other values of V_{b}. G varies from 10 to approximately 150 for other bias voltages.

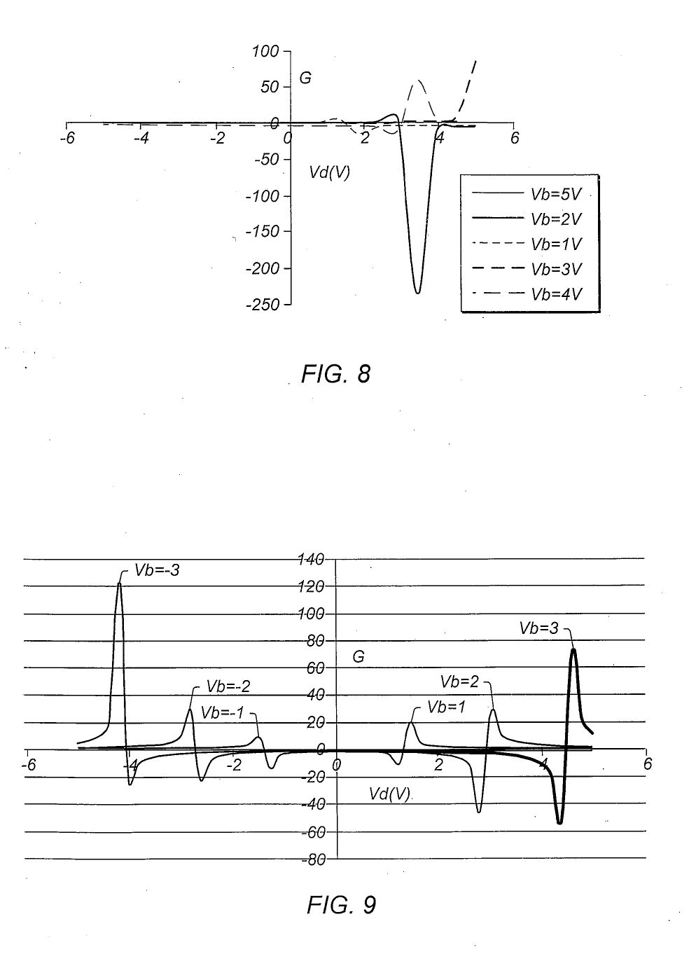

As a comparison, FIG. 8 depicts gain factor (G) versus bias voltage for ceramic samples of a similar material, IHC45. Both PsB and IHC 45 are n-type wide band gap materials with band gap E_{g}>about 2.3 eV. IHC 45 is on the other hand is strongly ferromagnetic whereas PsB is weakly ferromagnetic to non-magnetic. It has been reported in literature that the band gap of these materials may have a range of about 2.2 eV to about 3.9 eV depending upon the processing history of these materials (for example in: J. Dou, L. Navarrete, P. Kale, P. Padmini, R. K. Pandey, H. Gao, A. Gupta and R. Schad, “Preparation and characterization of epitaxial ilmenite-hematite films”, J. Appl. Phys., 101, 920070,053908, and Z. Dai, H. Naramoto, K. Narumi, S. Yamamoto, and A. Miyashita, J. Appl. Phys., 85, (1999), 7433). Chemical stoichiometry of O₂ and the annealing environments may play a role in the final value of E_{g}.

In certain embodiments, a single crystal PsB device provides bipolar signal amplification (gain). Single crystal PsB provides significant output signal amplification as a consequence of applied bias voltage. The output signal amplification may have a well defined resonance as described herein. In certain embodiments, a signal amplification device using single crystal PsB is produced using standard CMOS processing techniques known in the art.

The mechanism for bipolar gain using the single crystal PsB is different than those for either an operation amplifier or a crystal oscillator. For an operation amplifier, an elaborate combination of circuit components (resistors, capacitors, and transistors) are matched to produce signal amplification. For a crystal oscillator, bipolar gain occurs as a consequence of frequency dependent resonance (in crystal oscillators, piezoelectric quartz crystals are used to generate frequency). It may also be noted that the single crystal PsB is not a piezoelectric because the existence of piezoelectricity is forbidden for centro-symmetric crystals.

Because large values of G are found in the range of the band gap (E_{g}), it appears that the bipolar nature of G is electronic in nature. In certain embodiments, growth of single crystal PsB using the high temperature solution growth method is simple and requires relatively modest resource investment. In some embodiments, the growth of single crystal PsB is scaled up. In some embodiments, single crystal PsB is grown by the Czochralski technique in large diameters as is the case for silicon boules that are used in microelectronics) because PsB is a congruently melting material.

In some embodiments, PsB is used in substrates for space or high-altitude electronics because PsB is a radhard material unlike classical semiconductor materials (such as silicon, germanium, gallium arsenide, etc.). In some embodiments, a PsB based device may be used in bioelectronics devices because of the biocompatibility of both Fe₂O₃ and TiO₂. Because the raw materials used to make PsB (hematite, Fe₂O₃ and rutile, TiO₂) are typically abundantly available, devices produced using PsB may be produced in large volumes at relatively low costs.

In certain embodiments, a single crystal PsB device is used in microelectronics circuits requiring signal amplification. For example, the single crystal PsB device may be used in handheld devices to amplify their output signal. In certain embodiments, a single crystal PsB device is used in circuits for radhard electronics and/or biomedical devices. In some embodiments, a single crystal PsB device is used as a current sensor and/or detector. In some embodiments, a single crystal PsB device is used for voltage calibration using the feature of a narrow and sharp resonance. In some embodiments, a single crystal PsB device is used as a current limiter.

In some embodiments, a device is made from a ceramic substrate of PsB instead of single crystal PsB. The PsB ceramic substrate may be made using high purity grade powder of pseudobrookite. High purity grade powder may be obtained from many suppliers of inorganic compounds as raw materials, for example, such as from Alfa Aesar Chemical Company (Ward Hill, Mass., U.S.A.). The PsB powder may be ball milled using, for example, vibratory ball mill equipment for 10-15 minutes, which produces PsB powder with particles of approximately 100-125 nm in size. This powder may then be calcined in air at 850° C. for one hour such that the particles form clusters of crystallized lumps, which then may be ground to fine powder using a mortar and pestle. This material may then be mixed with a PVA binder and allowed to dry in air, after which the material is packed in a stainless steel die for pressing into pellet form using, for example, the automatic Carver uniaxial press. The die may be heated at 400° C. and held there during the entire pressing process. The pressing may take place by applying a maximum force at 13,500 lbs. and holding it there for about 3 hours.

The pressing may form a green (unfired) pellet of approximately 13 mm in diameter by 5-6 mm high depending upon the amount of powder used. The pellet may be annealed in flowing argon at 1100° C. for 6-8 hours, which produces a dense pellet with uniform black color. Some parts of the pellets may develop hairline cracks. Ceramic substrates may be made out of un-cracked regions. Fine silver contacts may be made using a conductive silver epoxy to which fine silver wire may be attached for connecting to the ceramic substrates for use in taking measurements.

In certain embodiments, a device is produced using a ceramic substrate of PsB. The device may amplify electrical output signal when biased with an external biasing voltage. The characteristics of the ceramic substrate of PsB may be substantially similar to the characteristics described above for single crystal PsB. FIG. 9 shows gain factor (G) at various bias voltages for the ceramic substrate of PsB.

As shown in FIG. 9, G is plotted as a function of the drain voltage (V_{d}) while varying the bias voltage (V_{b}) in steps of ±1, ±2, and ±3 V. For each bias voltage, the gain takes place as well defined resonant peaks, similar to found for single crystal PsB. The magnitude of G for each biasing voltage, however, is substantially smaller than what is found for single crystal PsB.

Despite the smaller gain found for the ceramic substrate of PsB, a device using the ceramic substrate of PsB may still be used in several applications described herein for single crystal PsB. For example, the ceramic substrate of PsB may be used in certain areas of microelectronics, space circuits, biomedical electronics, and/or handheld devices such as mobile phones, music players, etc. The ceramic substrate of PsB may also be used for detecting currents and for calibration of voltage. When V_{b} is above about 3 V, however, the I-V characteristics of the ceramic substrate of PsB get distorted and a device may not be suitable for signal amplification.

The radhard nature of PsB based nonlinear I-V characteristics has been documented in “Multifunctional Nature of Modified Iron Titanates and their Potential Applications” and “Novel Magnetic-Semiconductors in Modified FeTiO₃ for Radhard Electronics”.

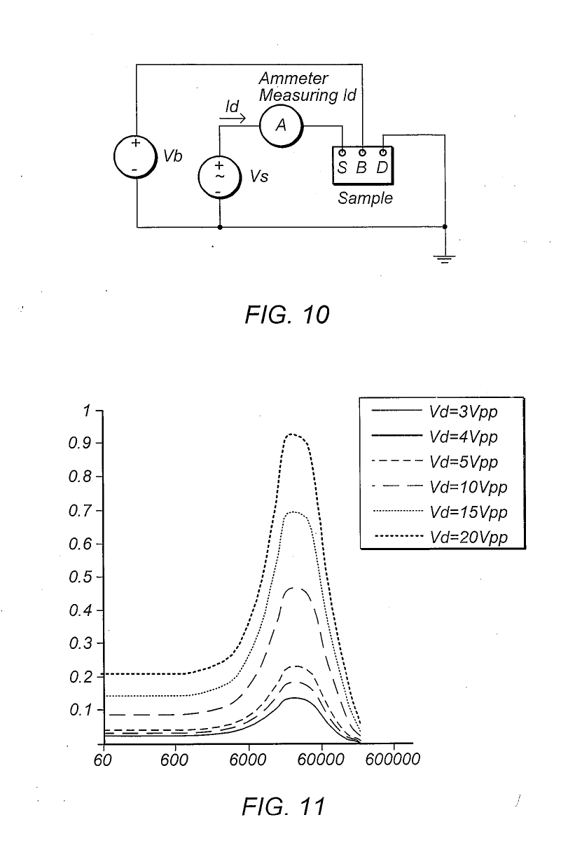

FIG. 10 depicts a circuit diagram used to determine the response of I-V in AC (alternating current) mode as a function of an AC bias voltage (V_{b}) for single crystal PsB (a 3-point I-V measurement). As shown in FIG. 10, the bias voltage applied between point B (bias) and ground was in DC mode while the voltage between point S (source) and point D (drain) was in AC mode. The circuit diagram depicted in FIG. 10 allowed for study of the dependence of the drain current (I_{d}) as a function of the drain voltage (V_{d}) in AC mode while varying the input frequency over a wide range. The drain voltage (V_{d}) was varied from 3 Vₚₚ to 20 Vₚₚ and the biasing voltage (V_{b}) was varied from 0 to 5 VDC. The frequency range was from 20 Hz to 2 MHz.

The frequency dependence of the drain current (I_{d}) as a function of drain voltage (V_{d}) is shown in FIG. 11 The bias voltage (V_{b}) was kept at a constant value of 3 V for each V_{d}. As shown in FIG. 11, the output signal (I_{d}) increases with the increasing values of V_{d}, as expected. For each value of V_{d} kept constant while changing frequency, the frequency dependence shows a common trend. The output signal increases with frequency reaching its peak around 20 kHz and then decreases to lower values at higher frequencies.

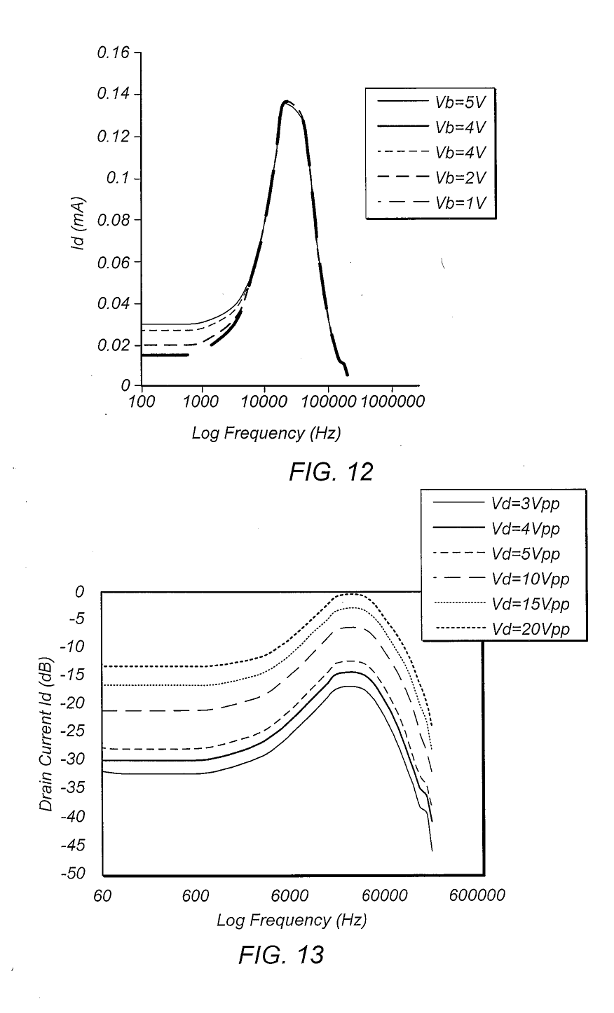

FIG. 12 depicts the frequency dependence of the drain current (I_{d}) as a function of bias voltage (V_{b}) at constant drain voltage (V_{d}=3 Vₚₚ). In contrast to FIG. 11, the drain current (I_{d}) in FIG. 12 increases with increasing frequency in small steps up to about 8 kHz, above which there is negligible increase in the output signal for the entire range of frequency. As in FIG. 11, the output signal reaches a maximum peak value at about 20 kHz in FIG. 12 as well, and then decreases with increasing frequency.

As shown by FIGS. 11 and 12, a tunable device may be made that is capable of tuning the output current as a function of V_{d} while applying a constant value of V_{b}. There is no need to change V_{b} because, as shown in FIG. 12, changing V_{b} has little to no effect on the output signal. Thus, in certain embodiments, single crystal PsB can be used in devices to provide signal amplification at low frequencies with a maximum frequency of about 20 kHz.

In certain embodiments, single crystal PsB can be used for audio amplification and/or filtering. Using conventional engineering practice, the output current shown in FIG. 11 can be converted to dB scale and depicted as a function of frequency, as shown in FIG. 13. As shown in FIG. 13, single crystal PsB can be used for audio amplification in a frequency range from about 20 Hz to about 20 kHz. Since the range of human hearing is from 20 Hz to 20 kHz, single crystal PsB may be used in an audio amplifier or filter capable of operation in the human hearing range. A cutoff point of such a device (e.g., a filter) may be about 58 kHz (the 3 dB point where the output signal is 70.7% of the original signal).

Conventional electronic filters consist of two sets of capacitors and resistors, one set being in series and one set being in parallel. This hybrid circuit is then manipulated by adjusting the capacitance (C) and resistance (R) values to produce the desired output. Such filters work solely by selecting appropriate values of C and R as dictated by the design of the desired device.

Single crystal PsB does not use any external components (such as capacitors or resistors) to operate as a filter. A single crystal PsB filter may operate based on the materials properties of the PsB in the operating range of about 20 Hz to about 20 kHz with a cutoff point of about 58 kHz. A single crystal PsB filter may have significantly less time delay than a conventional electronic filter because the filter operates based on the materials properties of the PsB. Single crystal PsB has a high dielectric constant, well defined non-linear I-V characteristics, n-type semiconducting nature, and relatively high electron mobility. A filter using single crystal PsB may obtain its filter characteristics from the materials properties of the single crystal PsB.

In certain embodiments, single crystal PsB is used in a simple device that is capable of manipulating the output current from very low frequencies to a maximum of 20 kHz. In some embodiments, a device is made from a ceramic substrate of PsB instead of single crystal PsB. In some embodiments, PsB is used in devices for space or high-altitude electronics because PsB is a radhard material. In some embodiments, a PsB based device may be used in bioelectronics devices because of the biocompatibility of both Fe₂O₃ and TiO₂. Because the raw materials used to make PsB (hematite, Fe₂O₃, and rutile, TiO₂) are typically abundantly available, devices produced using PsB may be produced in large volumes at relatively low costs.

In certain embodiments, PsB is used in a device such as a tunable signal amplifier. For example, the PsB device may be used in handheld devices such as, but not limited to, cell phones, hearing aids, MP3 players, and radios. In certain embodiments, PsB is used in a variable gain amplifier.

High quality chemicals were used in proper proportions to produce ceramic samples with the composition of IHC45. Processing parameters were followed that are identical to those found in “Nonlinear current-voltage characteristics of ilmenite-hematite ceramic”, “Magnetization and Curie Temperature of Ilmenite-Hematite Solid solution Ceramics”, and R. K. Pandey, P. Padmini, R. Schad, J. Dou, H. Stern, R. Wilkins, R. Dwivedi, W. J. Geerts and C. O'Brien, “Novel Magnetic-Semiconductors in Modified FeTiO₃ for Radhard Electronics”, J. Electro-Ceramic, DOI 10.1007/s10832-007-9390-1, (2008); (2009) 22:334-341.

After pressing and annealing, pellets of primarily two diameters were obtained: 24-25 mm and 12-13 mm. The thickness of the pellets varied from about 3-5 mm, which was dependent upon the amount of IH powder used. The pellets were first analyzed for their crystalline structure by XRD (X-ray diffraction analysis) and for composition by EDAX (Energy Dispersion X-ray analysis). Ceramic samples of IHC45 were polished to a high shine and then cut into small rectangular slabs. Silver point electrodes were placed as evenly spaced three dots on one of the surfaces. Very fine silver wires were used to connect them to a precision parametric analyzer (PA), which is integrated with a PC for data collection.

The current-voltage (I-V) characteristics of IHC45 were determined using a two point current-voltage measurement in DC (direct current) mode (using a circuit as shown in FIG. 3). Two point measurements were obtained to establish the general behavior of the Schottky diode (metal-semiconductor diode) and compare the measurements with the I-V characteristics reported in:
Feng Zhou, Sushma Kotru and Raghvendra K. Pandey, “Nonlinear current-voltage characteristics of ilmenite-hematite ceramic” Materials Letter, 57, (2003), 2104; L. Navarette, J. Dou, D. M. Allen, R. Schad, P. Padmini, P. Kale and R. K. Pandey, “Magnetization and Curie Temperature of Ilmenite-Hematite Solid solution Ceramics”, J. Am. Ceram. Soc., 89(5), (2006), 1601;
R. K. Pandey, P. Padmini, R. Schad, J. Dou, H. Stern, R. Wilkins, R. Dwivedi, W. J. Geerts and C. O'Brien, “Novel Magnetic-Semiconductors in Modified FeTiO₃ for Radhard Electronics”, J. Electro-Ceramic, DOI 10.1007/s10832-007-9390-1, (2008); (2009) 22:334-341;
P. Padmini, M. Pulikkathara, R. Wilkins and R. K. Pandey, “Neutron radiation effects on the nonlinear current-voltage characteristics of ilmenite-hematite ceramics”, Applied Physics Letters, 82(4), (2003), 586;
P. Padmini, S. Ardalan, F. Tompkins, P. Kale, R. Wilkins and R. K. Pandey, “Influence of proton radiation on the current-voltage characteristics of ilmenite-hematite ceramics”, J. Elec. Mats, 34(2), (2005), 1095;
D. M. Allen, L. Navarrete, J. Dou, R. Schad, P. Padmini, P. Kale and R. K. Pandey, S. Shojah-Ardalan and R. Wilkins, “Chemical ordering in ilmenite-hematite bulk ceramics through proton irradiation”, Apply. Phys. Lett. 85, (2004), 5902; and
R. K. Pandey, H. Stern, W. J. Geerts, P. Padmini, P. Kale, J. Dou, and R. Schad, “Room Temperature Magnetic-Semiconductors in Modified Iron Titanates Their Properties and Potential Microelectronic Devices”, Advances in Science and Technology, 54, (2008), 216.

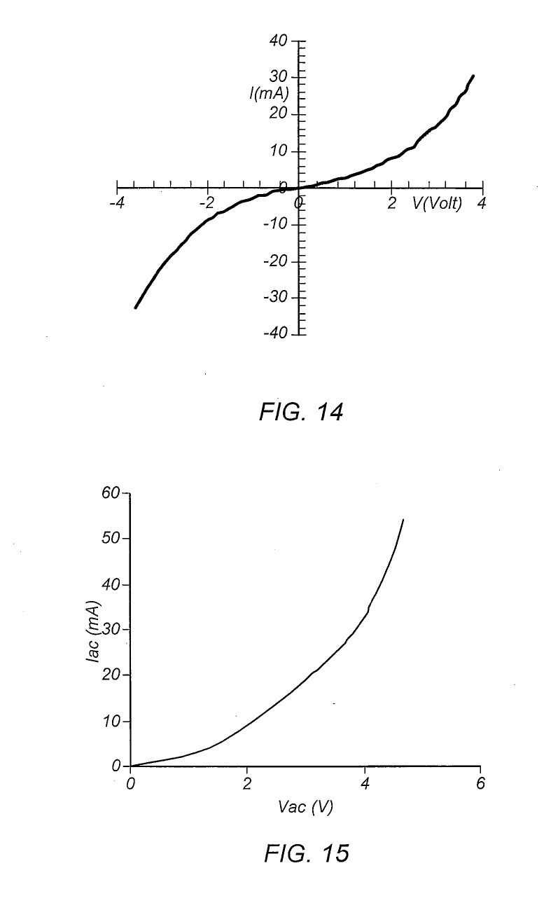

FIG. 14 depicts the I-V curve found for the IHC45 ceramic sample. The I-V curve confirms the Schottky effect taking place for the IHC45 ceramic sample. FIG. 14 shows the varistor nature of the I-V curve for the IHC45 ceramic sample. The diode characteristics of IHC45 in AC mode was determined using a circuit similar to as shown in FIG. 10. The range of frequency was from 20 Hz to 2 MHz. As shown in FIG. 10, the bias voltage applied between bias (B) and ground was in DC mode while the voltage between source (S) and drain (D) was in AC mode. This allowed the study of the dependence of the drain current (I_{d}) as a function of drain voltage (V_{d}) in AC mode while varying the input frequency in a wide range.

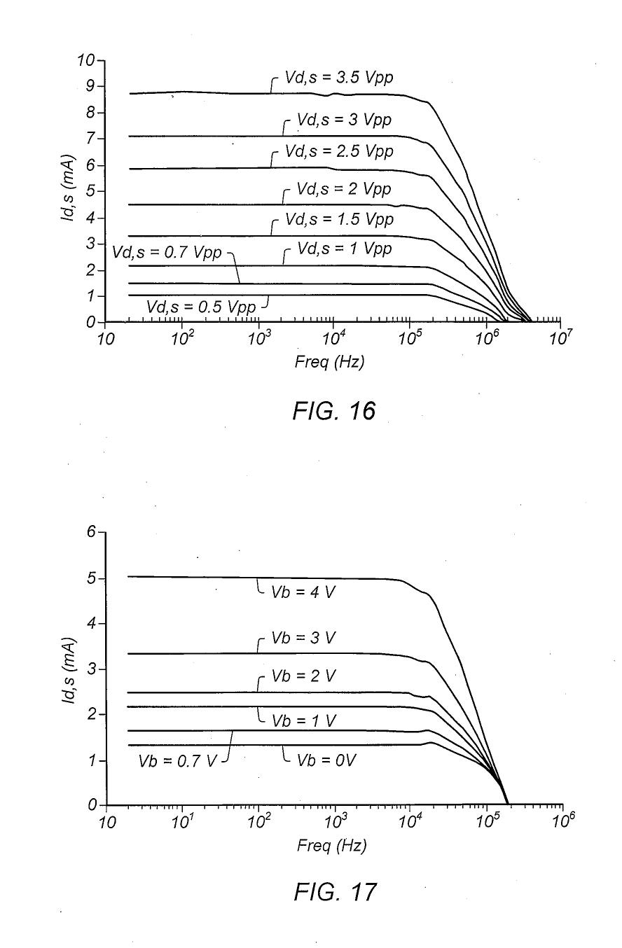

FIG. 15 shows the I-V of a typical IHC45 ceramic sample diode in AC mode at 60 Hz frequency. FIG. 16 depicts the I-V characteristics of IHC45 ceramic sample with AC input at varying frequencies and varying drain voltage (V_{d}) and fixed bias voltage (V_{b}). FIG. 17 depicts the I-V characteristics of IHC45 ceramic sample with AC input at varying frequencies and varying bias voltage (V_{b}) and fixed drain voltage (V_{d}).

FIGS. 16 and 17 show that I_{d} increases with the increase of V_{d} or V_{b}, which is to be expected. For each value of V_{b} or V_{d}, however, the drain current (I_{d}) remains unaltered for all frequencies up to about 350 kHz. Above this frequency, I_{d} abruptly drops to almost zero. Such a signal to frequency characteristic may form the basis for an electronic low pass filter. This property of IHC45, and perhaps of other iron-titanates that are examples of magnetic-semiconductors, may provide material for making an efficient low pass filter device with a cutoff frequency equal to 20 kHz. Such a device may be made relatively inexpensively and may have applications in audio-frequency range.

FIGS. 16 and 17 also show that the level of current at the drain, I_{d}, increases with both increasing V_{b} (DC) and V_{d} (AC). This feature may allow one to adjust the output current by changing either the input V_{b} or V_{d} according to the mode of operation of the device.

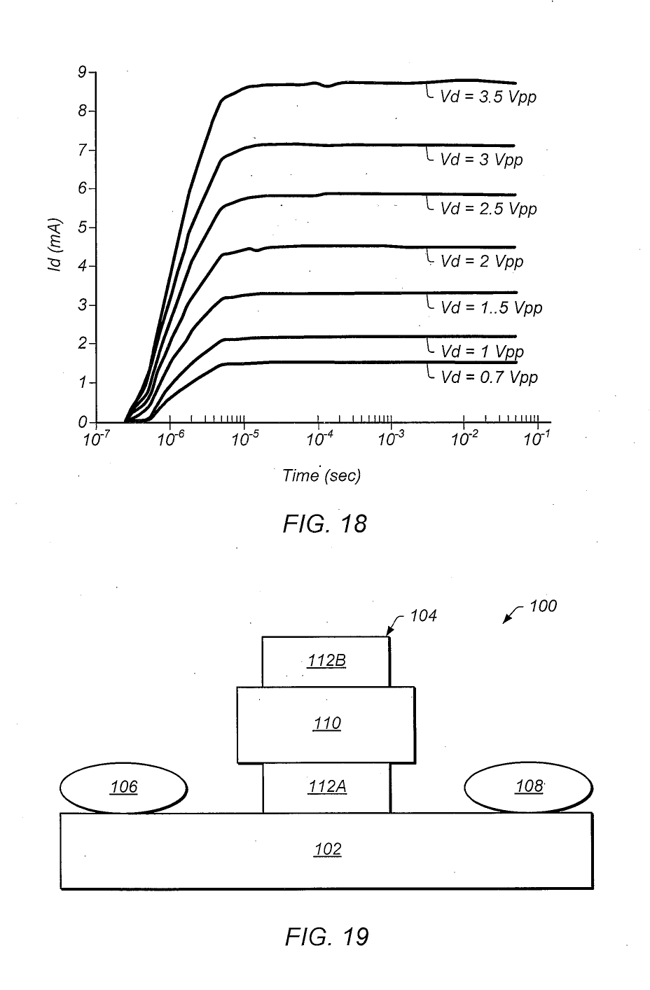

FIG. 18 depicts the output signal, I_{d}, as a function of time (inverse of the frequency) for IHC45 ceramic. FIG. 18 shows that an IHC45 device may be used for switching purposes. As shown in FIG. 18, the transition speed for the IHC45 device is such that the output reaches its final value in less than 10 us regardless of the driving voltage. Switching speeds of this magnitude are sufficient for frequencies less than the 20 kHz bandwidth limit of the low pass filter.

Conventional low pass filters typically consist of combinations of discrete passive electronic components such as capacitors, inductors, and ohmic (linear) resistors. The values of the combined discrete components forming the filter are adjusted to determine the range of frequency below which the filter will allow the signal to pass through and above which the signal transport will be inhibited. The combination of these components determines the output signal, which is a function of the input voltage.

In certain embodiments, a low pass filter using an IHC45 ceramic substrate does not necessitate the use of any discrete external components such as resistors or capacitors. In certain embodiments, the IHC45 low pass filter's filtering properties are based solely on the materials properties of IHC45 (e.g., the intrinsic resistive and capacitive properties of IHC45). In addition to the intrinsic resistive and capacitive properties of IHC45, IHC45 exhibits a high dielectric constant, non-linear I-V characteristics, and magnetism (therefore, inductance). These properties are all properties suitable for device development. Additionally, IHC45 is a wide band gap semiconductor of n-type conduction.

In certain embodiments, the materials properties of IHC45 are utilized to provide desired filter (e.g., low pass filter) properties. In some embodiments, adjustments to the bias voltage (V_{b}) modify and adjust the low pass filter properties. In some embodiments, IHC45 is ferromagnetic at room temperature and the IHC45 device is able to operate in the presence of a magnetic field with some change in output signal. The non-linear I-V characteristics of IHC45 have been reported in: “Novel Magnetic-Semiconductors in Modified FeTiO₃ for Radhard Electronics”; “Room Temperature Magnetic-Semiconductors in Modified Iron Titanates Their Properties and Potential Microelectronic Devices”; and R. K. Pandey, P. Padmini, P. Kale, J. Dou, C. Lohn, R. Schad, R. Wilkins and W. Geerts, “Multifunctional Nature of Modified Iron Titanates and Their Potential Applications”, Ceramic Transactions of Am. Ceramic Society, Vol. 226, (2011), 61, 61-75.

In certain embodiments, the IHC45 ceramic substrate device operates satisfactorily in an irradiated environment. The radhard properties of IHC45 and similar other iron titanates have been previously provided in: “Novel Magnetic-Semiconductors in Modified FeTiO₃ for Radhard Electronics”; “Neutron radiation effects on the nonlinear current-voltage characteristics of ilmenite-hematite ceramics”; “Influence of proton radiation on the current-voltage characteristics of ilmenite-hematite ceramics”; and “Chemical ordering in ilmenite-hematite bulk ceramics through proton irradiation”. Because of this property of IHC45, an IHC45 low pass filter device may be important in the emerging field of radhard electronics. Because the raw materials used to IHC45 are typically abundantly available, devices produced using IHC45 may be produced in large volumes at relatively low costs.

In certain embodiments, IHC45, or similar oxide semiconductors, are used to produce transistor devices. These transistor (e.g., varistor-transistor hybrid) devices may operate based on modified current-voltage (I-V) characteristics of IHC45. In some embodiments, the modifications are produced using a gate voltage applied through a gate insulator (gate oxide) as in a MOS (metal-oxide-semiconductor) type structure between a source and a drain. In some embodiments, the modifications are produced using a bias voltage between the source and the drain. In yet further embodiments, the I-V characteristics of a varistor may be modified by a magnetic field. Such devices may be used as current controlled voltage source (CCVS) devices and/or voltage controlled current source (VCCS) devices. Such devices may also exhibit all the characteristics of a conventional transistor.

FIG. 19 depicts a schematic representation of an embodiment of structure 100. Structure 100 may be used to produce a varistor-transistor hybrid device. Structure 100 includes substrate 102 with MO (metal-oxide) structure 104, source 106, and drain 108 formed on the substrate. In certain embodiments, substrate 102 is an IHC45 substrate. Substrate 102 may be, for example, a highly polished ceramic slab of IHC45. In some embodiments, substrate 102 is about 4 mm wide, about 7 mm long, and about 3 mm thick (height). Other dimensions may be suitable depending upon the desired application of the structure.

Because IHC45 is ceramic in nature, the IHC45 substrate may have a large number of grains (or crystallites) seeparated by thin amorphous wall layers called grain boundaries. Current transport between neighboring gains may be assumed to be either by a hopping mechanism or by tunneling. As described above, IHC45 is a wide bandgap semiconductor typically with a band gap E_{g}>2.3 eV. The band gap may have a range of about 2.2 eV to about 3.9 eV depending upon the processing history of the material (e.g., the chemical stoichiometry of O₂ and/or the annealing environment during processing of the material).

In some embodiments, substrate 102 includes another ilmenite-hematite substrate or iron-titanate such as IHC33, which has an Fe₂O₃ atomic concentration of 33 percent. Both IHC45 and IHC33 are ferromagnetic and n-type semiconductors and have similar properties. For example, both IHC45 and IHC33 are varistor materials and are radhard with a high degree of immunity to different types of radiation. The building blocks for these materials are high purity grade materials such as Fe₂O₃, FeO, and TiO₂ that are known to be biocompatible materials and are easily available at reasonable costs.

In certain embodiments, MO structure 104 includes gate oxide 110 sandwiched between metal contacts 112. Metal contacts 112 may be, for example, silver or gold contacts. In some embodiments, lower metal contact 112A is an epoxy metal contact (e.g., silver epoxy). In some embodiments, gate oxide 110 is about 2.5 mm wide, about 2.5 mm long, and about 1.25 mm thick (height). Other dimensions may be suitable depending upon the desired application of the structure.

In certain embodiments, gate oxide 110 is an oxide with a very high dielectric constant. For example, gate oxide 110 may have a dielectric constant greater than about 1000 at room temperature and 1 kHz frequency. In some embodiments, gate oxide 110 has a dielectric constant of between about 10⁴ and about 10⁵ at room temperature and 1 kHz frequency.

In one embodiment, gate oxide 110 is CaCu₃Ti₄O₁₂ (CCTO). CCTO belongs to the general class of perovskites with a body centered cubic unit cell. CCTO may be classified as a supercapacitor and has been proposed as a candidate for practical and affordable energy storage devices. CCTO is a stable oxide that is chemically compatible with ICH45. Thus, structure 100 may be annealed at relatively high temperatures to produce a well bonded and stress-free structure.

In certain embodiments, gate oxide 110 (e.g., CCTO) and substrate 102 (e.g., IHC45) are coupled together using, for example, a glue such as silver epoxy. The glue may be used as a lower electrode for gate oxide 110 (e.g., lower metal contact 112A). Following coupling of gate oxide 110 and substrate 102, the structure may be cured at room temperature by, for example, subjecting the structure to heat provided by a simple IR (infrared) lamp for a selected amount of time (e.g., between about 30 and about 35 minutes). The structure may then be subsequently annealed in vacuum or argon at a higher temperature (e.g., about 800° C.) for an amount of time (e.g., about 3 hours).

After annealing of the structure, upper metal contact 112B may be formed on gate oxide 110. Upper metal contact 112B may be, for example, a silver or a gold contact. Contacts for source 106 and drain 108 may also be formed. In certain embodiments, contacts for source 106 and drain 108 are silver contacts because other metals such as gold may not produce the desired varistor effect in structure 100. Gold or other metals besides silver may form an ohmic contact with IHC45 substrates and other iron-titanate substrates that inhibits the varistor effect in the structure.

A circuit widely used for MOSFET devices (similar to the circuit depicted in FIG. 3) may be used to determine the modified I-V characteristics of structure 100 with substrate 102 being made from IHC45 using either the CCTO gate oxide (applied gate voltage through the gate oxide) or, as shown later, the bias voltage between the source and the drain. The determined, modified I-V curves may be assessed for the contributions made by an external agent—the gate oxide, the bias voltage, or a magnetic field. The net values of the contributions may be extracted using the following equation, in which the contribution of an external agent on the output signal of the varistor can be determined by using the relationship:

ΔSₑₓ=Sₙₑₜ−S₀ (4)

where ΔSₑₓ is the contribution of the external agent to the total signal Sₙₑₜ, and S₀ is the original signal in the absence of an external agent. The external agents could be a magnetic field, an electric field, a bias voltage, or an injected current. In many situations, the contribution of the external agent can be determined using the simple equation (4).

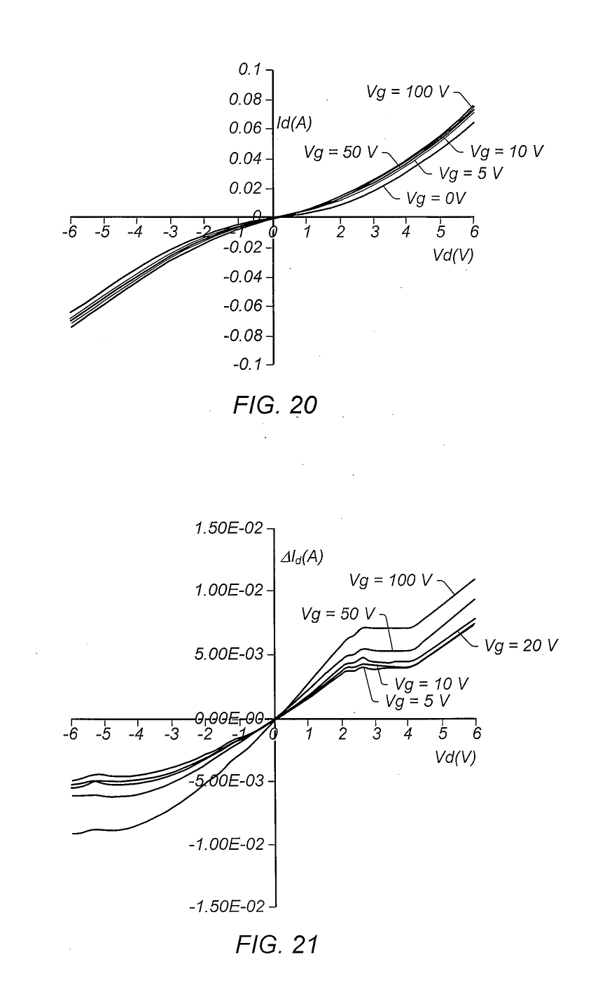

FIG. 20 depicts I-V curves for structure 100 as a function of applied gate voltage, V_{g}. Two important features are shown in the curves of FIG. 20. First, there is a small, but definite change in the level of drain current, I_{d}, for each value of gate voltage applied even though, as depicted in FIG. 20, the change may be barely noticeable. Second, each curve passes through the (0,0) coordinate, which is significant because when changes are induced by a bias voltage (as shown later), the curves shift along the drain voltage, V_{d}, axis and give rise to changes in the switching voltage of the varistor.

Transistor drain current, ΔI_{d}, due to the gate voltage may be extracted from the total drain current, I_{d,x}, for each value of the gate voltage. FIG. 21 depicts the net transistor drain current plotted as a function of the drain voltage. The curves in FIG. 21 show that structure 100 has the I-V characteristics of a typical transistor.

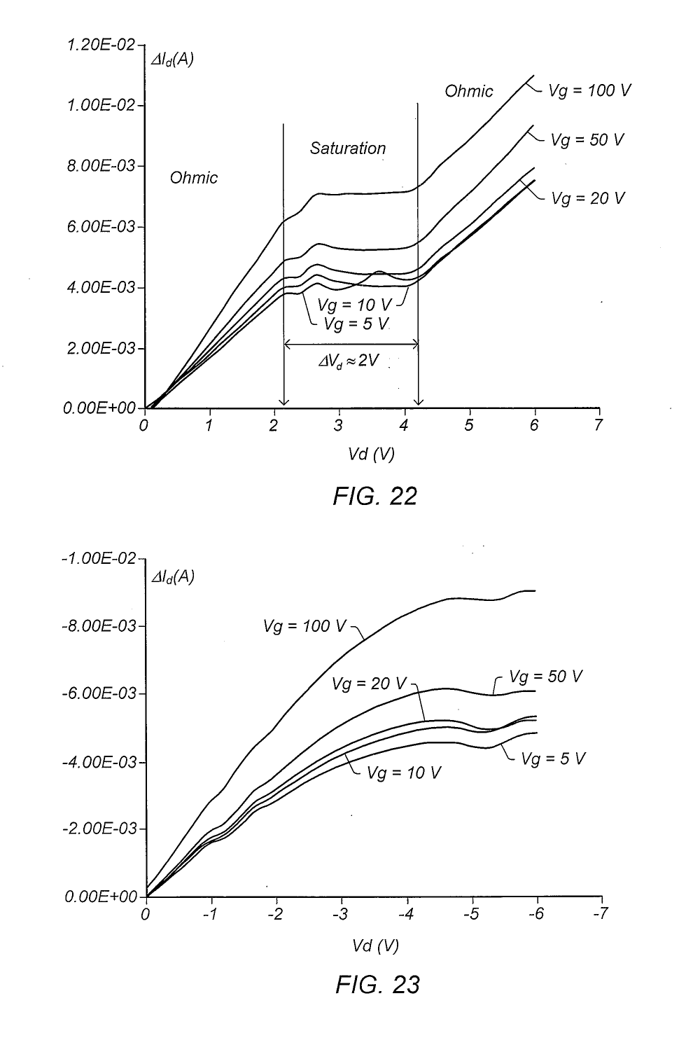

Structure 100 may also be shown to be a bipolar device as the I-V curves assume distinctly different shapes in the forward and reverse modes of operation, as shown in FIGS. 22 and 23. FIG. 22 depicts I-V curves for structure 100 for positive drain voltage, V_{d}, as a function of gate voltage. The I-V curves are shown to have three distinct regions—two “ohmic” regions separated by a region labeled as “saturation” region. Additionally, there is some evidence of fluctuations in the output current between approximately 2.2 V and 4.2 V of drain voltage. The width of this region (about 2 V) is near the quantity of the bandgap for IHC45 so it may be possible the effect is related to the bandgap of IHC45.

The curves in the ohmic regions of the curves in FIG. 22 may also show effects of the bandgap of IHC45. The first ohmic region (0V<V_{d}<2.2V) has a slope of 3×10⁻³. The second ohmic region (4.2V<V_{d}<6V) has a slope of 1.36×10⁻³, which is only about 45% of the value for the first ohmic region. A similar trend may also be found when a bias voltage is applied. The difference in slopes may indicate that the bandgap of IHC45 affects the shape of the I-V curve in the “saturation” region during charge transport from the metal to the semiconductor.

FIG. 23 depicts I-V curves for structure 100 for negative drain voltage, V_{d}, as a function of gate voltage. As shown in FIG. 23, in the reverse mode, structure 100 exhibits the characteristics of a typical transistor except for the presence of some minor fluctuations in current.

In certain embodiments, structure 100 may produce larger drain currents (on the order of tens of mA) than a traditional transistor using an insulating film (such as silicon oxide or silicon nitride that is commonly used as a gate oxide for transistors) in the presence of a modest electric field. For example, in structure 100, an electric field produced by the gate voltage (V_{g}=10 V-100 V) applied to CCTO gate oxide 110 (thickness of approximately 1.25 mm) is significantly smaller than an electric field produced by the insulating film of 50 nm thickness with V_{g} of just a few millivolts. In addition, structure 100 may produce little or no heating effect in the presence of an electric field.

Knowledge of the transconductance of a transistor plays an important role in microelectronics. Transconductance, gₘ, may be given by:

gₘ=(drain current)/(gate voltage)=I_{d}/V_{g}≈;ΔI_{d}/ΔV_{g}; (5)

or, when bias voltage is the agent of change then:

gₘ=(drain current/bias voltage=I_{d}/V_{b}≈ΔI_{d}/ΔV_{b}. (6)

The unit for gₘ is S (or, Ω⁻¹) and is an important parameter in designing current or voltage amplifiers using a transistor. For a conventional transistor, gₘ is usually on the order of a few mS. The mutual resistance (or trans-resistance), rₘ, is the reciprocal of gₘ (rₘ=gₘ⁻¹). The voltage amplification of a transistor is higher with larger values of rₘ. The results of the determination of this parameter is presented in Table I for both IHC 45 and PsB crystal along with their potential applications.

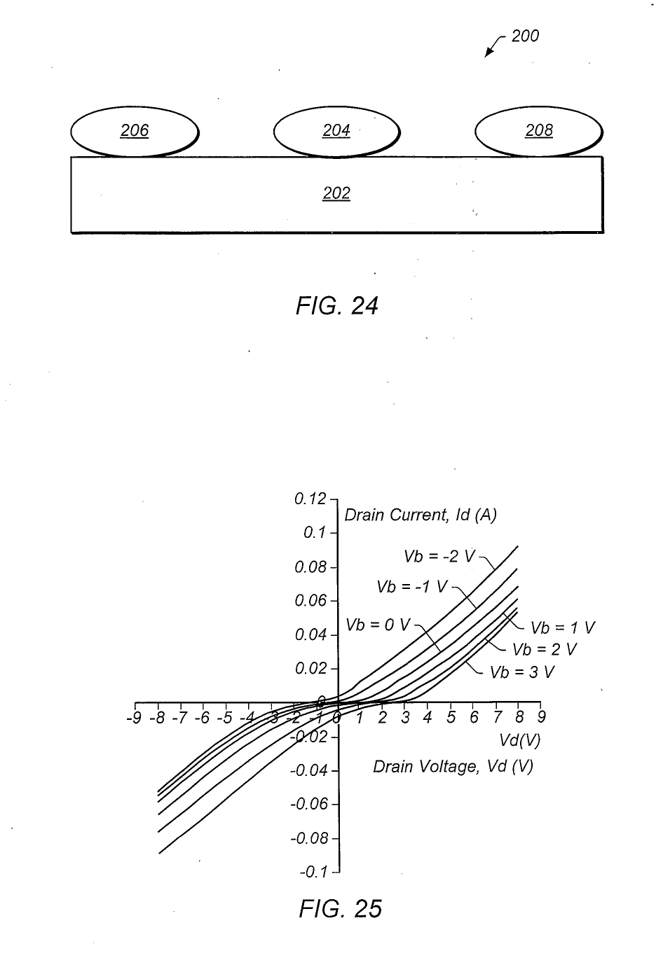

FIG. 24 depicts a schematic representation of an embodiment of structure 200. Structure 200 may be used to study the effect of a biasing voltage on drain current using, for example, an IHC45 substrate. Structure 200 includes substrate 202 with bias contact 204, source 206, and drain 208 formed on the substrate. In certain embodiments, substrate 202 is an IHC45 substrate. Substrate 202 may be, for example, a highly polished ceramic slab of IHC45. Bias contact 204, as well as contacts for source 206 and drain 208, may be silver contacts.

FIG. 25 depicts I-V curves for structure 200 with the bias voltage, V_{b}, ranging between ±1-3 V and the drain voltage, V_{d}, ranging between ±8 V. The I-V curves shown in FIG. 25 show a distinction from the I-V curves for structure 100 with gate oxide 110 (shown in FIG. 20). As shown in FIG. 25, the switching voltage of the varistor shifts along the V_{d} axis as the bias voltage changes.

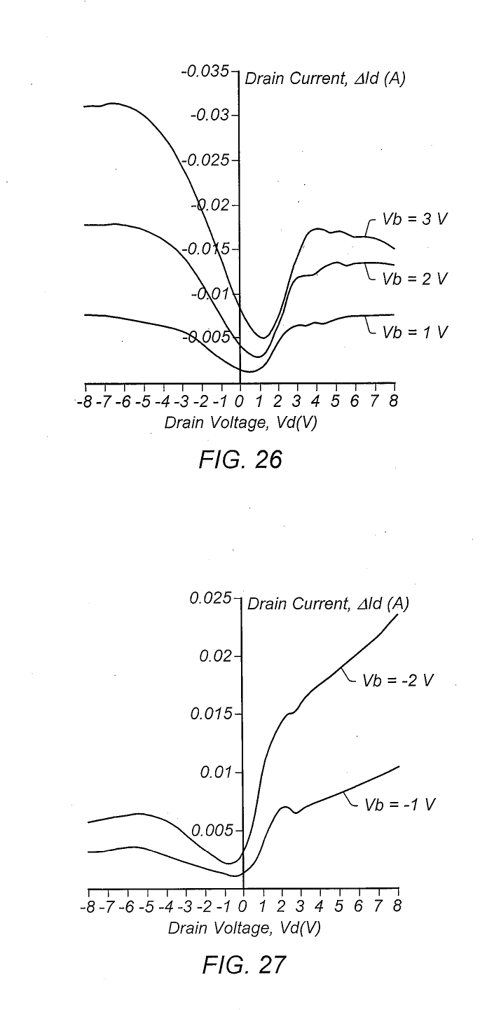

Equation (4) above may be applied to the I-V curves in FIG. 25 to extract transistor current ΔI_{d} as a function of applied bias. FIG. 26 depicts I-V curves for structure 200 as a function of positive bias voltage. FIG. 27 depicts I-V curves for structure 200 as a function of negative bias voltage. FIGS. 26 and 27 show a transistor effect for structure 200 with saturation of the drain currents occurring for V_{d}>−5 V. Saturation at such drain currents may provide a good transistor. The curves in FIGS. 26 and 27 also show a large current amplification for a small change in bias voltage.

Structure 200 also exhibits a bipolar nature similar to structure 100. There are, however, differences in the bipolar behavior of structure 200 as compared to structure 100 (shown in FIGS. 21-23). For example, for structure 200, the minimum of current (the null point) does not coincide with V_{d}=0. For positive values of V_{d}, the null point shifts toward a higher value of V_{d} (e.g., 1<V_{d}<2). Additionally, the null point along the current axis increases as V_{b} increases. The effect of voltage on the null point may be the result of changing potential heights associated with the applied bias voltage. A similar behavior of I-V is found for negative values of V_{b}, as shown in FIG. 27. The I-V curve in FIG. 27 also shows a small fluctuation in the drain current for V_{d} between +2 V and +3 V.

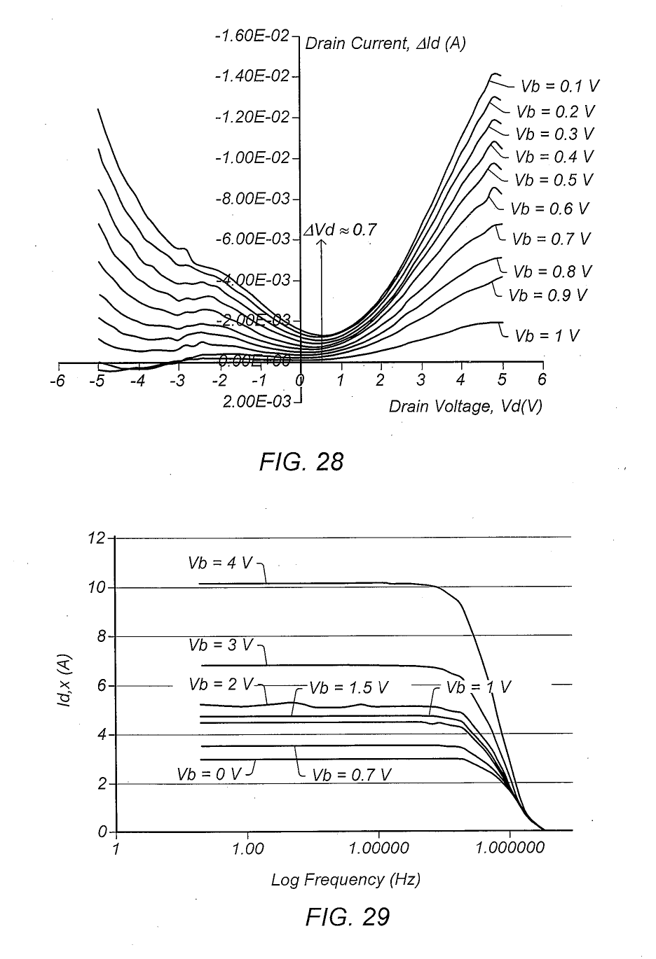

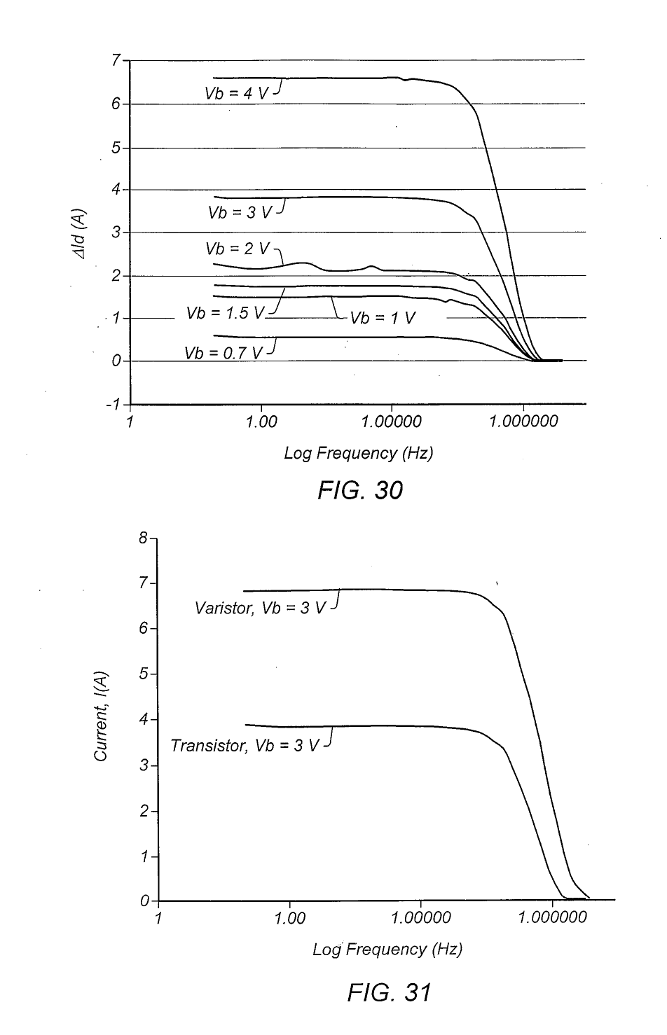

FIG. 28 depicts I-V curves for structure 200 as a function of small values of the bias voltage (e.g., V_{b}≦1 V). As shown in FIG. 28, structure 200 may continue to provide good response at values of V_{b}≦1 V. The bipolar behavior and the dependence of current on bias voltage for structure 200 are also shown in FIG. 28. The saturation of drain current, however, is not shown in any of the curves in FIG. 28. As shown in FIG. 28, structure 200 has a null point corresponding to V_{d} 0.7 V. FIGS. 29 and 30 depict data showing the frequency dependence of output current for structure 200. A circuit similar to the circuit depicted in FIG. 10 was used to determine the modified I-V characteristics of structure 200. FIG. 29 depicts the frequency dependence of output current for structure 200 in varistor mode while keeping the drain voltage constant at 2 Vₚₚ. The bias voltage range in FIG. 29 is 0 V to 4 V. The curves in FIG. 29 show that the output current increases in tandem with an increase in bias voltage. The output current is also shown to remain substantially constant for a wide range of frequency (e.g., log frequency).

As discussed earlier the contribution of the external bias voltage may be extracted from the total output current of the varistor mode to obtain the characteristics of structure 200 in its transistor mode. FIG. 30 depicts the frequency dependence of output current for structure 200 in transistor mode while keeping the drain voltage constant at 2 Vₚₚ. FIG. 31 depicts the difference between the varistor mode and the transistor mode for structure 200 at a constant bias voltage of 3 V. The 3 dB point, which is the characteristic upper frequency limitation point of an amplifier, is found to be at approximately 310 kHz for the transistor mode and 420 kHz for the varistor mode. These 3 dB point numbers indicate that structure 200 should perform well up to these frequencies.

In certain embodiments, other modified iron-titanates such as PsB (pseudobrookite) are used as substrates in structure 100 or structure 200 described above. PsB may be used as substrate 102 or substrate 202 with only minor modifications to the structures described above. Thus, PsB may be used as a substrate in a varistor-transistor hybrid device as described above. PsB, or other iron-titanates, may be used as a substrate in either ceramic, single crystal, or film form. Ceramic substrates may be less expensive and more suited for large scale integration and high volume production.

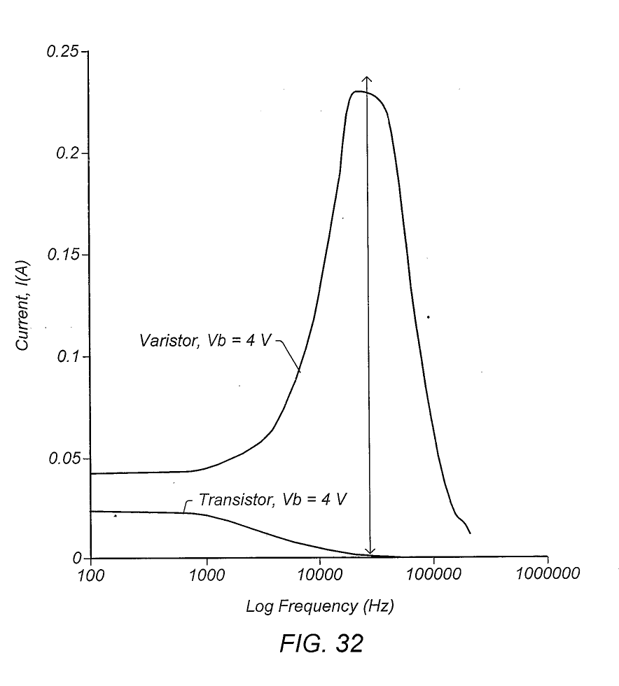

FIG. 32 depicts the difference between the varistor mode and the transistor mode for structure 200 with the PsB substrate at a constant bias voltage of 4 V. The 3 dB point for the PsB substrate is found to be 58 kHz in the varistor mode and 3 kHz in the transistor mode. Thus, the PsB substrate has a small frequency range in the transistor mode, which may limit the usefulness of the PsB substrate for transistor applications such as small signal applications. The PsB substrate in transistor mode may, however, still be useful for applications where high frequency dependence is not necessary such as 60 Hz power applications. The PsB substrate in varistor mode may be suitable for many applications such as, for example, an amplifier covering the range of the human auditory system (20 Hz to 20 kHz), which may be useful for handheld devices.

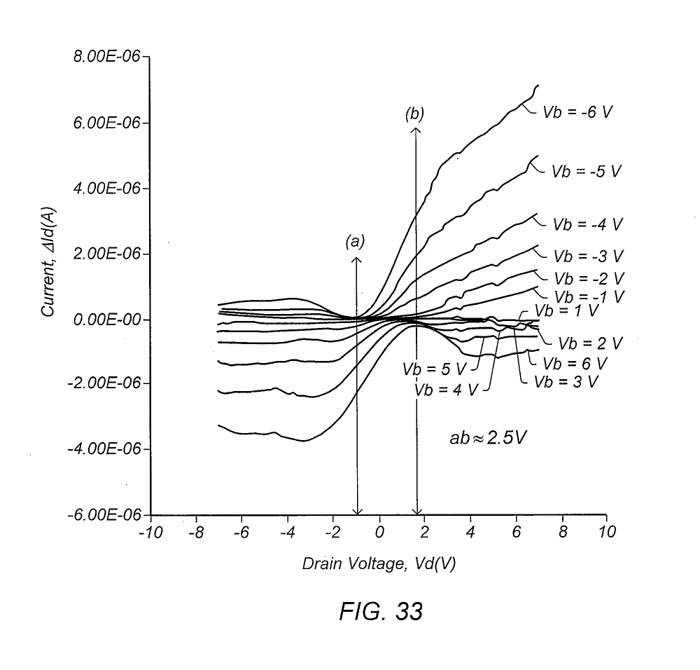

The effect of biasing voltage on the drain current may also be studied using structure 200 with the PsB substrate. FIG. 33 depicts a composite of several I-V curves for the PsB substrate as a function of varying bias voltage, V_{b}. The bias voltage varies between 1 V and 6 V in both the positive (forward) and negative (reverse) directions of V_{d} (V_{b} varies between ±1 V-±6 V). The curves in FIG. 33 depict the bipolar nature of the PsB substrate structure. The null points for both the forward and reverse directions are indicated by the two parallel lines, (a) and (b), shown in FIG. 33. Lines (a) and (b) are separated by about 2.5 V, which interestingly is near the band gap of PsB (about 2.3 eV). Thus, it may be possible that the two null points being located away from the (0,0) origin may be because of the band gap of PsB.

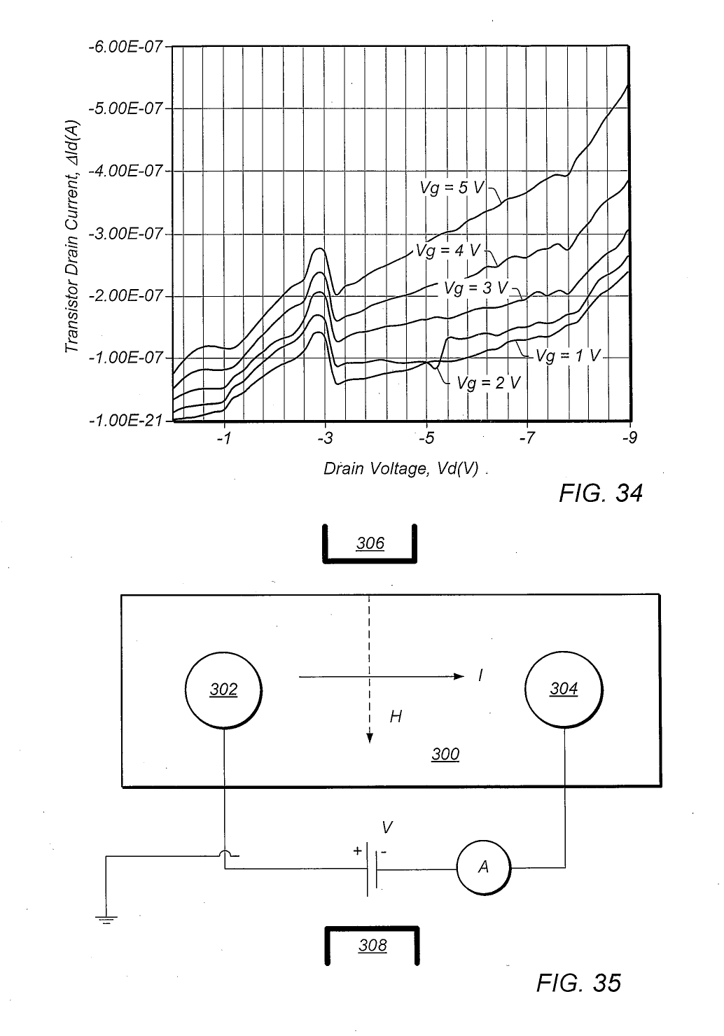

FIG. 34 depicts transistor drain current versus drain voltage as a function of gate voltage for structure 100 with a PsB substrate (e.g., substrate 102 is PsB) and SiO₂ as the gate oxide (e.g., gate oxide 110 is SiO₂). The gate oxide was formed by sputter deposition on a single crystal PsB substrate using an RF magnetron sputtering system under high vacuum. EDAX and XRD analyses were used to confirm the formation of SiO₂.

As shown in FIG. 34, the gate voltage was varied from +1 V to +4 V. The level of change in the drain current confirms the active nature of the gate oxide and the presence of the transistor effect in the structure with the PsB substrate. PsB, as described above, is an n-type semiconductor with little to zero ferromagnetism and a band gap of about 2.3 eV. As described above, PsB is also a radhard material with excellent varistor properties. The presence of the oscillation in the curves in FIG. 34 is because of the very low values of the drain currents. The curves also show a peak at about −3 V drain voltage, which, at this point, is unexplained.

Table I depicts the values of the transconductance and transresistance found using equations (5) and (6).

TABLE I
Transfer Functions and Potential Applications

| | Trans- | | Trans- | | |
|---|---|---|---|---|---|
| | conductance | | resistance | | Potential |
| Device Type | gₘ | | rₘ | | Applications |
| I. PsB Single Crystal: | | | | | |
| Voltage biased I-V | | | | | |
| I.1 @ constant V_{d} = +6 V | 1.37 | μS | 730 | kΩ | CCVS |
| | | | | | (current |
| | | | | | controlled |
| | | | | | voltage |
| | | | | | source) |
| I.2 @ constant V_{d} = −6 V | −663 | nS | −1.51 | MΩ | CCVS |
| II. IHC45 Ceramic with | | | | | |
| CCTO as gate insulator: | | | | | |
| field effect | | | | | |
| II.1 @ constant V_{d} = +3.36 V | 31.64 | μS | 31.60 | kΩ | CCVS |
| II.2 @ constant V_{d} = −3.36 V | −35.07 | μS | −28.51 | kΩ | CCVS |
| III. IHC Ceramic: | | | | | |
| voltage biased I-V | | | | | |
| III. 1 @ constant V_{d} = | 9.7 | mS | 103.1 | Ω | VCCS |
| +4.02 V | | | | | (voltage |
| | | | | | controlled |
| | | | | | cuurent |
| | | | | | source) |
| III.2 @ constant V_{d} = | −10.2 | mS | −98.0 | Ω | VCCS |
| −4.02 V | | | | | |

FIG. 35 depicts a schematic for determining the effect of a magnetic field, H, on the I-V characteristics of a varistor. Substrate 300 may be a highly polished rectangular slab of IHC45 of approximately 5 mm×3 mm×1 mm in size. Two silver pads 302, 304 may be formed on the surface of substrate 300. One pad may operate as the source (e.g., pad 302) and the other pad may operate as the drain (e.g., pad 304) for monitoring the current (I) with potential applied (V). The current direction (I) is shown going from pad 302 to pad 304. An external magnetic field, H, may be generated using, for example, N-pole 306 and S-pole 308. Other devices for generating the external magnetic field may also be used (e.g., an electromagnetic device). The magnetic field, H, and the current, I, may be kept perpendicular to each other.

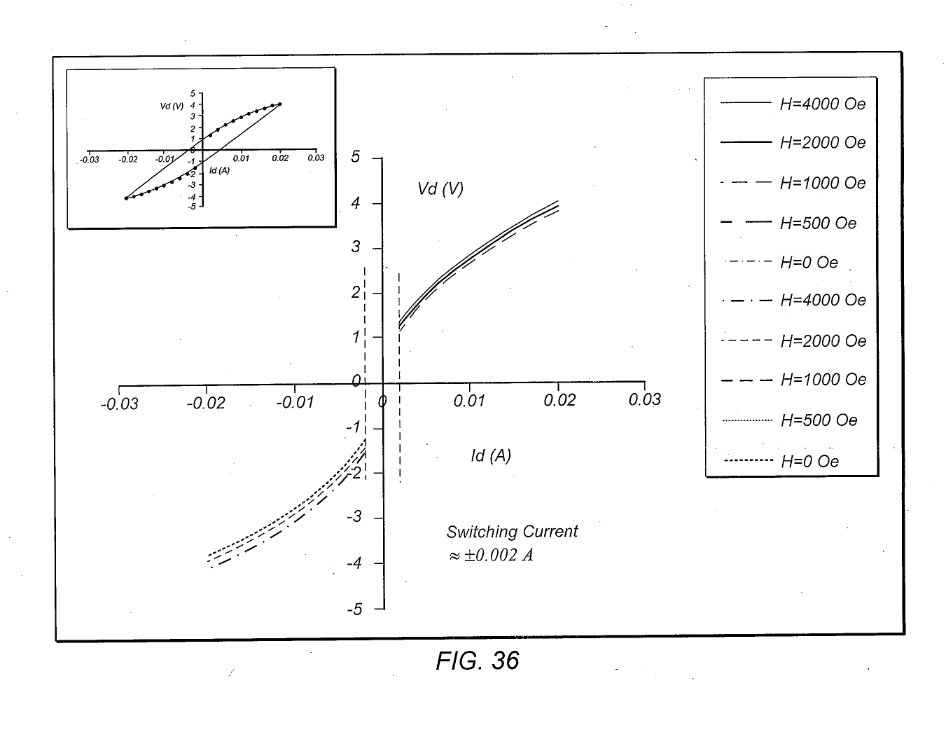

FIG. 36 depicts the effect of magnetic fields, H, on the V-I characteristics of the IHC 45 varistor at room temperature. These curves show that the output voltage increases with an increase in the input current for each increase of the magnetic field, H. In FIG. 36, it is shown that: (a) the device switches at currents ≈±2 mA; and (b) the switching from the forward mode to the reverse mode of the diode is accompanied by a hysteresis loop, as shown as an example in the insert.

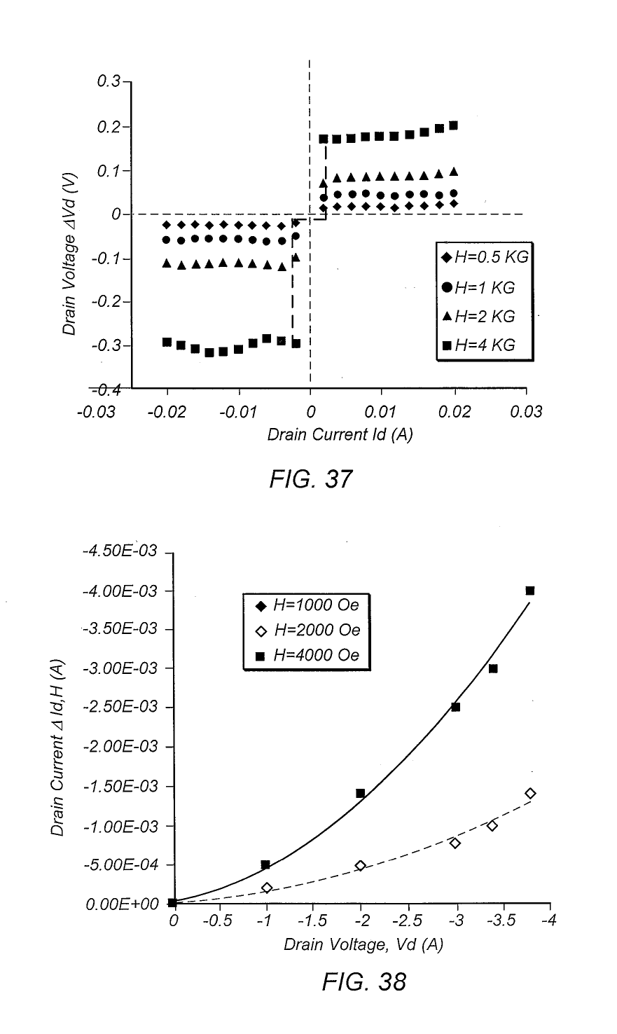

FIG. 37 depicts V_{d}-I_{d} characteristics of the IHC45 transistor with varying magnetic fields. FIG. 37 shows the bipolar nature of the transistor and the strong field dependence of output voltage. For both the forward and reverse modes, the switching takes place around 2 mA like in the case of the varistor as discussed before. It behaves like a voltage amplifying transistor for the entire range of ±drain current. The output signal is also strong with well-defined saturation; and it increases with the increasing H-field. In this mode the device can be used as a voltage amplifier and a sensor. It is interesting to note also that the device goes through a much larger gain in the reverse mode when H=4 kOe than when it is in the forward mode. Nevertheless, the gain corresponding to H=4 kOe is the largest in both the modes of operation.

FIG. 38 depicts the ΔI_{d}-V_{d} of the IHC 45 transistor in reverse mode with varying H at room temperature. FIG. 38 depicts these transistor curves for negative values of the drain current for the IHC 45 substrate. FIG. 38 shows that the maximum signal gain is achieved when the field approaches 4 kOe. For H<2 kOe, the output signals may be rather weak and may be too small in magnitude to be of any practical value.

From FIGS. 36-38, it may be concluded that the varistor using the IHC45 substrate can be tuned using an external magnetic field and in this mode the device can be used as a magnetic field sensor. It is to be noted that in place of the IHC 45 substrate, other iron-titanates such as PsB can be used for producing magnetically tuned varistors. Further, the hybrid device may be used both as a magnetically tuned voltage amplifying transistor and/or as a magnetically tuned current amplifying transistor.

Potential applications of the device using the structure of FIG. 35 may include, but not be limited to, magnetically controlled voltage amplifiers, magnetically controlled current amplifiers, sensors, memory elements, microphone pickup with integrated pre-amplifier using a single transistor, and high temperature electronics. Because the IHC 45 substrate remains ferromagnetic up to about 610 K (≈335 degree Celsius), it has the potential to serve these roles when other ferromagnetic materials have exceeded their Curie temperature limits.

Unlike high speed silicon or GaAs based transistors, transistors using iron-titanates (e.g., IHC 45, IHC 33, PsB, Mn—PsB, etc.) as substrates may not have sufficient switching speeds for high-speed switching microelectronics applications. However, transistors using such substrates may be more robust, be simpler in structure, capable for operating at high temperatures, capable of withstanding radiation exposure, and have a range of frequency that makes such transistors suitable for power electronics and audio applications. For example, the varistor-transistor hybrid nature of the above-described structures may make the structures suitable as a single device that is able to be used in both switching applications and surge suppression applications. Varistor-transistor devices using the structures described above may be used in such applications as, but not limited to, electronic and audio amplifiers, electronic switches, filters, handheld devices, and in space and high temperature (radhard) electronics applications where robustness is desired. In certain embodiments, devices using the structures described above are suited for use as acoustic amplifiers covering the range of human hearing, current controlled voltage sources (CCVS), and/or voltage controlled current sources (VCCS).

It is to be understood the invention is not limited to particular systems described which may, of course, vary. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a device” includes a combination of two or more devices and reference to “a material” includes mixtures of materials.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A semiconductor device, comprising:
an iron-titanate substrate;
a gate oxide structure comprising:
a first metal contact on the substrate;
a gate oxide formed on the first metal contact; and
a second metal contact formed on the gate oxide; and
a metal source and a metal drain formed on the substrate on opposing sides of the gate oxide structure.

2. The device of claim 1, wherein the device operates as a transistor when a gate voltage is applied to the device.

3. The device of claim 1, wherein the device comprises a field effect transistor device.

4. The device of claim 1, wherein the iron-titanate substrate comprises a ceramic substrate.

5. The device of claim 1, wherein the iron-titanate substrate comprises 55% (atomic) ilmenite and 45% (atomic) hematite.

6. The device of claim 1, wherein the gate oxide comprises CaCu₃Ti₄O₁₂ (CCTO).

7. The device of claim 1, wherein the first metal contact comprises a silver epoxy that bonds the gate oxide to the substrate.

8. (canceled)

9. The device of claim 1, wherein the metal source and the metal drain comprise silver.

10. (canceled)

11. A semiconductor device, comprising:
an iron-titanate substrate;
a metal bias voltage contact formed on the substrate; and
a metal source and a metal drain formed on the substrate on opposing sides of the metal bias voltage contact.

12. The device of claim 11, wherein the device operates as a transistor when a biasing voltage is applied to the device.

13. The device of claim 11, wherein the iron-titanate substrate comprises a ceramic substrate.

14. The device of claim 11, wherein the iron-titanate substrate comprises pseudobrookite (PsB).

15. The device of claim 11, wherein the iron-titanate substrate comprises 55% (atomic) ilmenite and 45% (atomic) hematite.

16. The device of claim 11, wherein the metal bias voltage contact comprises silver.

17. (canceled)

18. (canceled)

19. (canceled)

20. A semiconductor varistor device, comprising:
an iron-titanate substrate;
a metal source and a metal drain formed on the substrate; and
a magnetic field generating device for generating a magnetic field in a direction perpendicular to a flow of current between the source and the drain.

21. The device of claim 20, wherein the iron-titanate substrate comprises a ceramic substrate.

22. The device of claim 20, wherein the iron-titanate substrate comprises 55% (atomic) ilmenite and 45% (atomic) hematite.

23. The device of claim 20, wherein the magnetic field generating device comprises opposite magnetic poles positioned on opposite sides of the substrate.

24. The device of claim 20, wherein the metal source and the metal drain comprise silver.

25. (canceled)

26. The device of claim 20, wherein the generated magnetic field is used to tune the varistor device during use.

27-53. (canceled)
